(19) United States
(12) Patent Application Publication
(10) Pub. No.: US 2025/0087640 A1
(43) Pub. Date: Mar. 13, 2025

(54) LOW ENERGY AND SMALL FORM FACTOR PACKAGE

(71) Applicant: QUALCOMM Incorporated, San Diego, CA (US)

(72) Inventors: Mustafa BADAROGLU, San Diego, CA (US); Zhongze WANG, San Diego, CA (US); Woo Tag KANG, San Diego, CA (US); Periannan CHIDAMBARAM, San Diego, CA (US)

(21) Appl. No.: 18/465,900

(22) Filed: Sep. 12, 2023

(51) Int. Cl. H01L 25/065; H01L 23/00; H01L 25/18; H10B 80/00

(52) U.S. Cl. CPC H01L 25/0657; H01L 24/08; H01L 25/18; H10B 80/00; H01L 2224/08145; H01L 2225/06541

(57) ABSTRACT

Disclosed are packages that may include first and second substrates with first and second chips therebetween. The first chip may be a logic chip and the second chip may be a processing near memory (PNM) chip. The active side of the first chip may face the first substrate and the active side of the second chip may face the second substrate. The first chip may be encapsulated by a first mold, and the second chip may be encapsulated by a second mold. The first and/or the second molds may be thermally conductive. A third chip (e.g., a memory) may be on the second substrate opposite the second chip. The second substrate may include very short vertical connections that connect the active sides of the second and third chips.

### FIELD OF DISCLOSURE

This disclosure relates generally to semiconductor devices, and more specifically, but not exclusively, to a low energy and small form factor package, such as a low energy and small form factor processing near memory accelerator (e.g., for mobile processors), and fabrication techniques thereof.

### BACKGROUND

Integrated circuit (IC) technology has achieved great strides in advancing computing power through miniaturization of active components. However, for certain applications there is a memory wall. That is, there is no solution for high-capacity high bandwidth (BW) memory for large artificial intelligence (AI) workloads such as ChatGPT. High bandwidth memory (HBM) can be used to some degree. Unfortunately, they are expensive and have high energy per bit due to lateral routing on the interposer. Also, they come with increased form factor due to side-by-side placement with the compute chiplet.

Accordingly, there is a need for systems, apparatus, and methods that overcome the deficiencies of conventional devices including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary package is disclosed. The package may comprise a first substrate and a second substrate above the first substrate. The package may also comprise a first chip on an upper surface of the first substrate and below the second substrate. First bumps on an active side of the first chip and may face and electrically couple to the first substrate. The first bumps may be configured to carry signals to and/or from the first chip. The package may further comprise a second chip on a lower surface of the second substrate and above the first chip. Second bumps on an active side of the second chip may face and electrically couple to the second substrate. The second bumps may be configured to carry signals to and/or from the second chip. The package may yet comprise a first mold on the upper surface of the first substrate and below the second substrate. The first mold may at least partially encapsulate side surfaces and a non-active side surface of the first chip. The package may yet further comprise a second mold on the lower surface of the second substrate and above the first mold. The second mold may at least partially encapsulate side surfaces and a non-active side surface of the second chip. The first chip and the second chip may be vertically aligned with each other, at least partially.

A method of fabricating a package is disclosed. The method may comprise providing a first substrate and a second substrate above the first substrate. The method may also comprise providing a first chip on an upper surface of the first substrate and below the second substrate. First bumps on an active side of the first chip and may face and electrically couple to the first substrate. The first bumps may be configured to carry signals to and/or from the first chip. The method may further comprise providing a second chip on a lower surface of the second substrate and above the first chip. Second bumps on an active side of the second chip may face and electrically couple to the second substrate. The second bumps may be configured to carry signals to and/or from the second chip. The method may yet comprise forming a first mold on the upper surface of the first substrate and below the second substrate. The first mold may at least partially encapsulate side surfaces and a non-active side surface of the first chip. The method may yet further comprise forming a second mold on the lower surface of the second substrate and above the first mold. The second mold may at least partially encapsulate side surfaces and a non-active side surface of the second chip. The first chip and the second chip may be vertically aligned with each other, at least partially.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIGS. 1-4 illustrate examples of conventional packages.

FIG. 5 illustrates an embodiment of a package in accordance with one or more aspects of the disclosure.

FIG. 6A-6D illustrate example stages of chip-first overmolding of chips in accordance with one or more aspects of the disclosure.

FIG. 7A-7D illustrate example stages of chip-last overmolding of chips in accordance with one or more aspects of the disclosure.

FIG. 8A-8F illustrate example stages of fabricating a package in accordance with one or more aspects of the disclosure.

FIG. 9A-9C illustrate example utilizations of a package in accordance with one or more aspects of the disclosure.

FIGS. 10-14 illustrate flow charts of example methods of fabricating a package in accordance with one or more aspects of the disclosure.

FIG. 15 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

As indicated above, currently there is no solution for high-capacity high bandwidth (BW) memory (HBM) for large AI workloads such as ChatGPT. HBM can be used to some degree. Unfortunately, they are expensive and have high energy per bit due to lateral routing on the interposer and overhead in circuits controlling 3D stacked DRAM dies with through-silicon-vias (TSVs). Also, they come with increased form factor due to side-by-side placement with the compute chiplet. Repetitive and regular workloads (e.g., matrix/vector to matrix multiplication) requiring high BW and capacity data in AI processing necessitate putting computation near the memory for high performance and energy efficient computation. Unfortunately, conventional processing in or near memory has limited flexibility, reduced logic performance (due to less performant technology inherent in the DRAM process), thermal-constrained computing, need for through-silicon via (TSV) process (which adds area and power overhead) in HBM. Also remaining are the inherent problems of high energy/bit and large form factor.

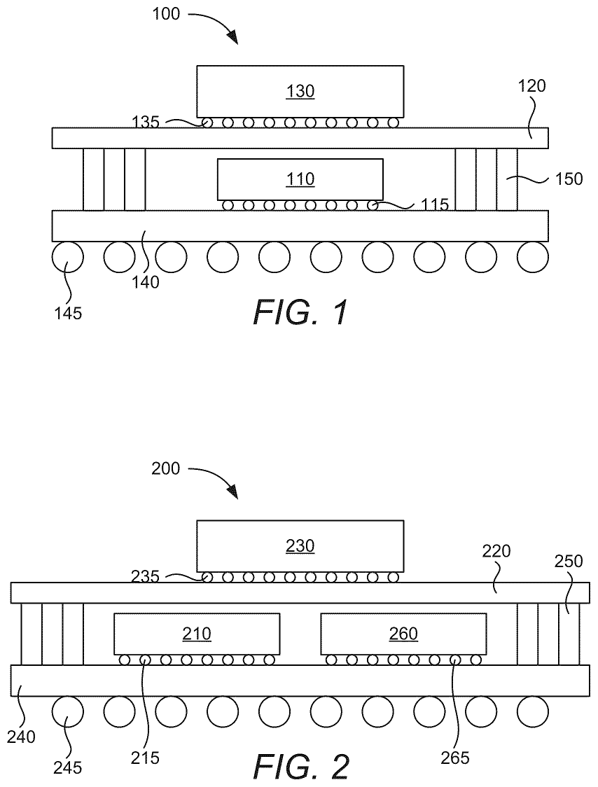

FIG. 1 illustrates a conventional package 100, which includes a logic die 110 on a fanout (FO) interposer 140. The package 100 may also be referred to as a stacked package since the components are stacked over each other. Solder balls 145 are on a lower surface of the FO interposer 140. The die bumps 115 of the logic die 110 are on an upper surface of the FO interposer 140. That is, the active side of the logic die 110 faces the FO interposer 140. The die bumps 115 are configured to carry signals to/from the logic die 110. A laminate substrate 120 is above the FO interposer 140 and above the logic die 110. Copper pillars 150 electrically connects the laminate substrate 120 and the FO interposer 140. Package-on-package (PoP) dynamic random-access memory (DRAM) 130 is on the laminate substrate. Note that DRAM bumps 135, configured to carry signals to/from the DRAM 130, are on an upper surface of the laminate substrate 120. This means that the active side of the DRAM 130 faces the laminate substrate 120. The package 100 does have a relatively good XYZ factor. That is, its dimensions (length, width, height) are relatively small.

However, all computation takes place in the logic die 110 (e.g., application processor (AP)). There is limited cache (e.g., SRAM) in the logic die 110 which requires more access to the PoP DRAM 130. This can limit speed since PoP DRAM 130 is relatively low bandwidth (BW) device. Note further that the pitches of the pillars 150 is very coarse. Also, connection paths between the logic die 110 and the PoP DRAM 130 through the FO interposer 140, the pillars 150, and the laminate substrate 120 can be lengthy. These factors can further limit the already slow bandwidth. Further, there can be high energy per bit DRAM access, which is disadvantageous in a platform such as a mobile device.

FIG. 2 illustrates another conventional stacked package 200, which is similar to the stacked package 100. That is, the stacked package 200 also includes a FO interposer 240, a logic die 210 (with die bumps 215 on upper surface of the FO interposer 240), solder balls 245 on lower surface of the FO interposer 240, a laminate substrate 220 above the FO interposer 240 and above the logic die 210, copper pillars 250 electrically connecting the laminate substrate 220 and the FO interposer 240, and a PoP DRAM 230 (with DRAM bumps 235 on upper surface of the laminate substrate 220). The conventional package 200 additionally includes a 2.5D DRAM 260 in between the laminate substrate 220 and the FO interposer 240. 2.5D DRAM bumps 265 are also on the upper surface of the FO interposer 240. That is, the active side of the 2.5D DRAM 260 faces the FO interposer 240. With the 2.5D (side-by-side) DRAM 260, the last level cache with logic provides higher BW access.

However, the capacity is still limited (e.g., up to 1 GB). The energy per bit is moderate. Unfortunately, the XY form factor increases. Also, the 2.5D signal routing complicates the input/output (I/O) fanout. Further, a more complex memory controller is required.

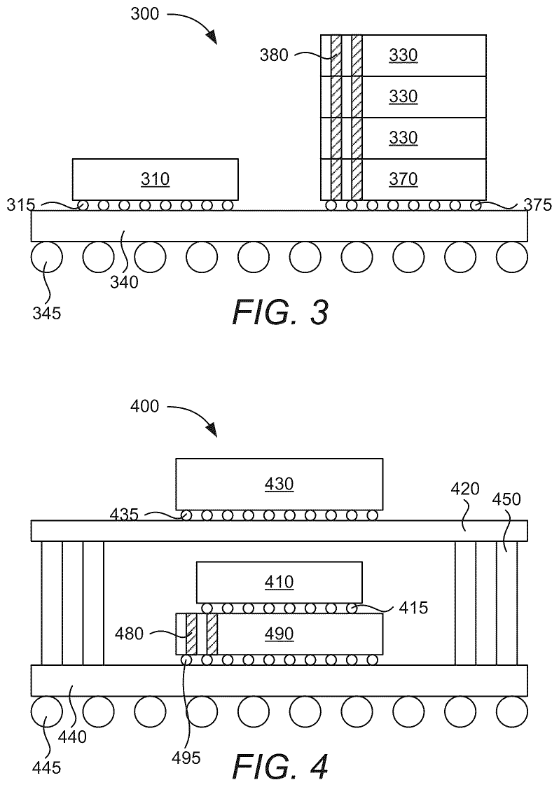

FIG. 3 illustrates yet another conventional stacked package 300 that includes a logic die 310 on an FO interposer 340 with solder balls 345 on its lower surface. The active side of the logic die 310 faces the FO interposer 340 (as evidenced by the die bumps 315 being on the upper surface of the FO interposer 340). The stacked package 300 also includes a PHY chip 370 with PHY bumps 375 on the FO interposer 340. A plurality of DRAMs 330 are stacked on the PHY chip 370. These can be high bandwidth memories (HBM). Communication between the PHY chip 370 and the DRAMs 330 are enabled by the through-silicon vias (TSV) 380. The PHY chip 370 facilitates memory access by the logic die 310. The 3D stacked HBMs next to logic die can provide high BW and high capacity.

Unfortunately, this still suffers from high energy per bit. Also, there is XYZ form factor penalty. Further, there is the need for TSV process. The side-by-side routing complicates the I/O fanout, and there is a need for a complex memory controller. In addition, the FO interposer 340 is expensive since it needs embedded silicon (Si) bridge to route signals between the HBM and the logic die 310.

FIG. 4 illustrates yet further conventional stacked package 400 that includes a static random-access memory (SRAM) 490 whose active side faces an FO interposer 440 (as evidenced by the SRAM bumps 495 being on the FO interposer 440). Solder balls 445 are on the lower surface of the FO interposer 440. An active side of the logic die 410 (evidenced by the die bumps 415) is on a non-active side of the SRAM 490. TSVs 480 enable the logic die 410 to access the SRAM 490. A laminate substrate 420 is above the FO interposer 440 and above the logic die 410. Copper pillars 450 electrically connect the laminate substrate 420 and the FO interposer 440, and a PoP DRAM 430 (with DRAM bumps 435 on upper surface of the laminate substrate 420).

With the conventional stacked package 400, all computations take place in the logic die 410. There is increased SRAM capacity with the 3D SRAM 490, but it is still not high as a DRAM. The increased SRAM capacity does slightly reduce DRAM access in certain workloads. However, it is still not effective in large artificial intelligence (AI) work models. There is still the need for the TSV process. Also, the bandwidth is relatively low and there is a high energy per bit access to the PoP DRAM.

To address these and other issues of conventional packages, it is proposed to provide packages that utilize low energy per bit schemes while maintaining a small form factor, e.g., for mobile applications. For example, processing near memory (PNM) accelerators may be face-to-face stacked with memory (e.g., DRAM) and they may be placed in a PoP configuration with a logic (e.g., compute) die. There can be significant technical advantages in using the proposed approach. They include (not necessarily exhaustive):
No need for TSV processes in any of the chips/dies (e.g., DRAM, PNM, logic).
Achieve small form factor in XYZ.
Little to no changes in the DRAMs—there may be changes in package routing and/or swapping DRAM IOs with lite IOs.
Innovative use of multiplexing/switching on the PNM die eliminating redundant signaling from DRAM to the compute die.
Lite-IOs in DRAM enabling high-BW and low-energy interface between DRAM and PNM.
Flexible PNM enabling high-speed test with integrated MBIST and high-speed access with memory controller.
Good thermal performance—DRAM+PDN on top, thermally conductive materials for heat spreading and dissipation.

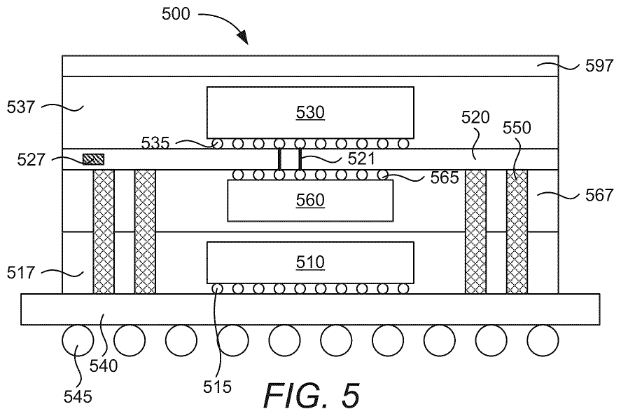

FIG. 5 illustrates a cross-section of an embodiment of a package 500 in accordance with one or more aspects of the disclosure. The package 500 may include a first substrate 540 and a second substrate 520 above the first substrate 540. In an aspect, each substrate may be viewed as a supporting material upon or within which elements of a semiconductor device or package are fabricated or attached. Substrates typically provide IC packages mechanical strength and provide capabilities to connect with external devices. The first substrate 540 may be a fanout (FO) interposer and may include one or more redistribution layers (RDLs) (not shown). One or more package balls 545 may be formed on a lower surface of the first substrate 540. Before proceeding further, it should be noted that terminologies such as “lower,” “upper,” “bottom”, “top”, “left”, “right”, etc. are used merely for convenience. Unless specifically indicated otherwise, these terminologies should NOT be taken to refer to absolute orientations or placements.

The second substrate 520 may be a coreless substrate and very thin. For example, a thickness of the second substrate 520 may be 70 μm or less. Indeed, it may be as thin as 20 μm or even thinner. The second substrate 520 may also include one or more RDLs (not shown). In particular, the second substrate 520 may include a plurality of vertical connections 521 whose pitches (center-to-center distances) are very small (e.g., 40 μm or less). The second substrate 520 may also include a plurality of lateral connections (not shown) for signal redistribution.

A first chip 510 may be provided or otherwise placed on an upper surface of the first substrate 540 and below the second substrate 520. The upper surface may be viewed as a top surface or an upper most surface of the first substrate. First bumps 515, which may be on an active side of the first chip 510, may face and electrically couple to the first substrate 540. For example, the first bumps 515 may be electrically connected (e.g., by direct contact) to the upper surface of the first substrate 540. The first bumps 515 may be configured to carry signals to and/or from the first chip 510. In this way, the first chip 510 may be electrically coupled with the first substrate 540. In an aspect, the first chip 510 may be a logic die (e.g., processor, processing core, etc.), and the first bumps 515 may be logic die bumps. Active side may be viewed as the side of the die or chip that includes active circuitry such as transistors to perform tasks. Conversely, a non-active side may be viewed as the side of the die or chip opposite the active side.

A second chip 560 may be provided or otherwise placed on a lower surface of the second substrate 520 and above the first chip 510. Second bumps 565, which may be on an active side of the second chip 560, may face and electrically couple to the second substrate 520. For example, the second bumps 565 may be electrically connected (e.g., by direct contact to the lower surface of the second substrate 520. The second bumps 565 may be configured to carry signals to and/or from the second chip 560. In this way, the second chip 560 may be electrically coupled with the second substrate 520. In an aspect, the second chip 560 may be a PNM die or chip, and the second bumps 565 may be PNM bumps.

A first mold 517 may be formed on the upper surface of the first substrate 540 and below the second substrate 520. The first mold 517 may encapsulate, at least partially, side surfaces and a non-active side (e.g., upper) surface of the first chip 510. The first mold 517 may be thermally conductive. For example, the thermal conductivity of the first mold 517 may be 1 W/m−K or greater. The first mold 517 may be formed from materials such as epoxy filled with Si3N4, filled with hybrid Si3N4/SiO2, and/or filled with SiO2.

A second mold 567 may be formed on the lower surface of the second substrate 50 and above the first mold 517. The second mold 567 may encapsulate, at least partially, side surfaces and a non-active side (e.g., lower) surface of the second chip 560. The second mold 567 may also be thermally conductive. For example, the thermal conductivity of the second mold 567 may be 1 W/m−K or greater. The second mold 567 may also be formed from materials such as epoxy.

The following should be noted regarding the first and second molds 517, 567. The first and second molds 517, 567 be made from same or varied materials. However, even when they are made from the same material, they may be separate. That is, they may be separately formed, and then put together so that they are in contact with each other. In this instance, there may be a distinct interface between the first and second molds 517, 567. Interface may be identified by OH bonds, different porosity orientation, resin/bonding-material at the interface, and/or grain surfaces of two sides mechanically bonded to each other.

The first and second molds 517, 567 may be thinned before putting them together. As a result, a total height of the first and second molds 517, 567 may be small, e.g., 200 um or less. This allows for very small Z form factor.

A third chip 530 may be provided or otherwise placed on an upper surface of the second substrate 520. Third bumps 535, which may be on an active side of the third chip 530, may face and electrically couple to the first substrate 540. For example, the third bumps 535 may be electrically connected (e.g., by direct contact) to the upper surface of the second substrate 520. As such, the third bumps 535 may face and electrically couple to the second chip 560 through one or more signal connections (including the vertical connections 521) within the second substrate 520. The third bumps 535 may be configured to carry signals to and/or from the third chip 530. In an aspect, the third chip 530 may be a memory chip (e.g., DRAM), and the third bumps 535 may be memory bumps.

A third mold 537 may be formed on the upper surface of the second substrate 520. The third mold 537 may encapsulate, at least partially, side surfaces and a non-active side (e.g., upper) surface of the third chip 530. The third mold 537 may be thermally conductive. For example, the thermal conductivity of the third mold 537 may be 1 W/m−K or greater. The third mold 537 may be formed from materials such as epoxy.

One or more through-mold vias (TMV) 550 may be formed between the first and second substrates 540, 520 within the first and second molds 517, 567. The one or more TMVs 550 may electrically couple the first and second substrates 540, 520 with each other. The TMVs 550 may be formed from conductive materials such as copper (Cu), tungsten (W), aluminum (Al), etc.

The package 500 may additionally include a lid (e.g., air lid) 597 on the third mold 537.

Within the second substrate 520, there may be one or more thin film transistors (TFT) 527 within the second substrate 520. For example, indium-gallium-zinc-oxide (IGZO) transistors may be example of a TFT transistor 527. At least one TFT transistor 527 may switch on/off an electrical connection between the first and second substrates through one of the TMVs 550. In an aspect, the operations of some or all of the TFT transistors 527 may be controlled by the second chip 560 (e.g., by the PNM chip). For example, the PNM chip 560 may control the TFTs 527 to cut off redundant switching from the memory chip 530 to the first chip 510 (e.g., a logic chip) when the PNM chip 560 is accessing the memory chip (530) or otherwise performing computation.

Note that the first chip 510, the second chip 560, and the third chip 530 may be vertically aligned with each other, at least partially. That is, the first chip 510, the second chip 560, and the third chip 530 may at least partially overlap vertically.

Note that pitches of the chip bumps (e.g., first bumps 515, second bumps 565, third bumps 535) can be very fine, e.g., 40 μm or less. Recall that the second substrate 520 can include vertical connections 521 of same or similar pitch. Thus, second bumps 565 (e.g., PNM bumps) may be vertically connected to the third bumps 535 (e.g., DRAM bumps). Also recall that the second substrate 520 is very thin. This means that the signal distance between second and third chips 560, 530 is very short. As a result, a high BW may be achieved. Also input/output (IO) switching can be very fast.

Further, in an aspect, the PNM chip 560 may be capable of performing a memory build-in self-test (MBIST) and other diagnostic functions for the memory chip 530. This can free the logic die 510 from performing such a function. Further, since the bandwidth between the PNM chip 560 and the memory chip 530 can be very high, such test and diagnostic functions may be performed efficiently.

The package 500 allows for some desirable technical advantages. These include (not necessarily exhaustive):
Double-sided DRAM and PNM stacking at double-sided FO/coreless-sub configuration.
TSV′ less triple stacking allowing DRAM+PNM+Logic.
Double planarization allowing z-height control supporting both chip-first and chip-last flow.
Direct vertical connections enabled by thin coreless substrate—reducing energy per bit.
PNM and/or interposer controlling the DRAM IO signaling allowing significant energy/bit reduction in the DRAM-to-PNM link.
Embodiment allowing not to touch the DRAM die/design—using enabling the use of existing DRAMs in the market.
Heat-spreading mold reducing hot spots.
Opportunity to further reduce the energy/bit and to increase BW by incorporating lite-IO to the DRAM die and/or TFT switches to the coreless interposer substrate.
PNM incorporating MBIST and diagnostic functions for DRAM for stand-alone testing of DRAM w/o a need for logic die.

Also, the package 500 enables integration of substrates without mechanical support (such as the second substrate 520 which may be coreless) in a triple stack configuration. The coreless substrate 520, which may be double-sided fanout interposer enables ultra-thin substrate. Normally, triple stack configuration is not a trivial task. The coreless substrate can be less than ⅓ thickness of conventional core substrates. A major challenge of coreless substrates is the difficulty associated with warpage. The package 500 solves that issue, while still maintaining a small form factor.

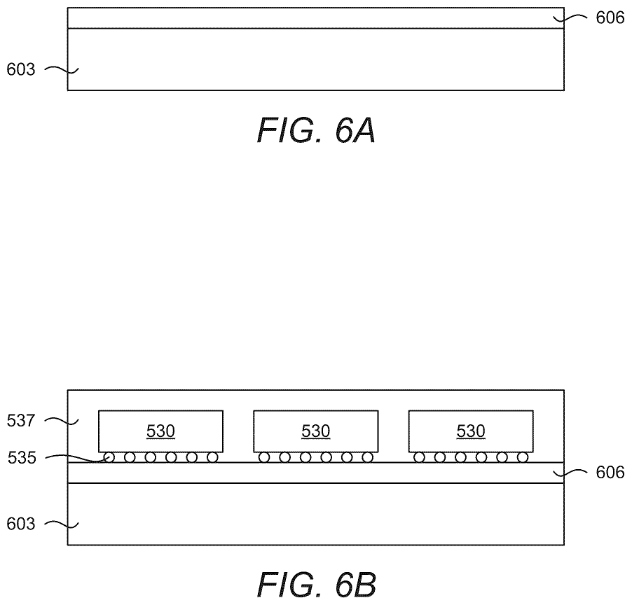

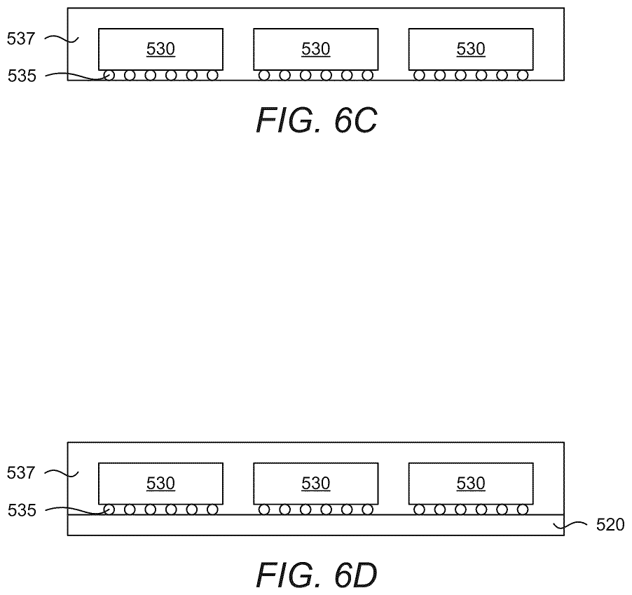

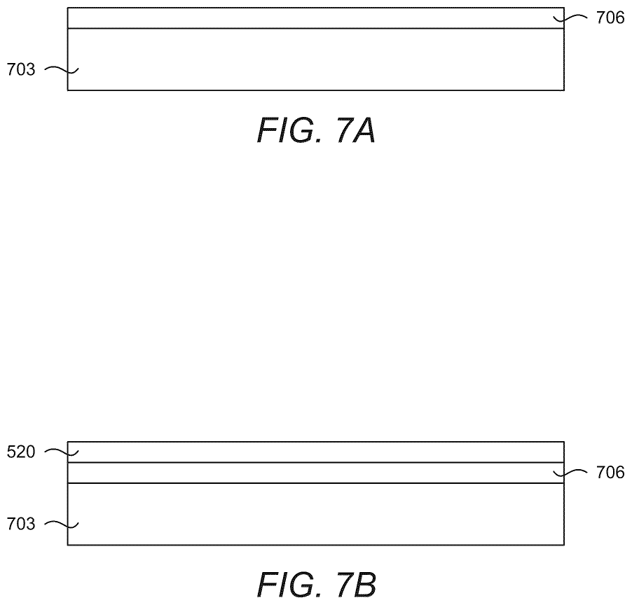

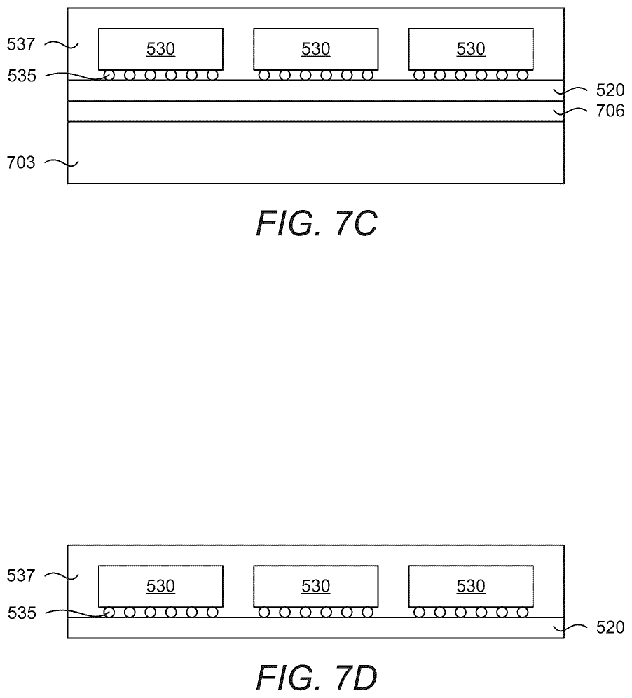

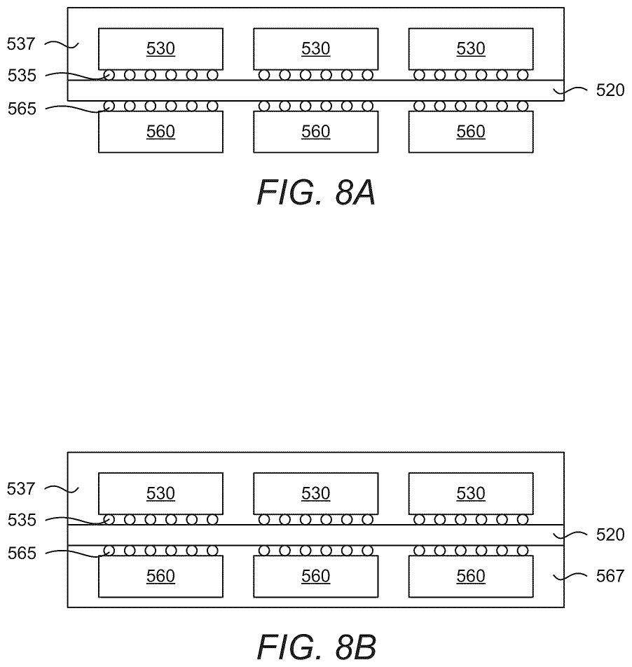

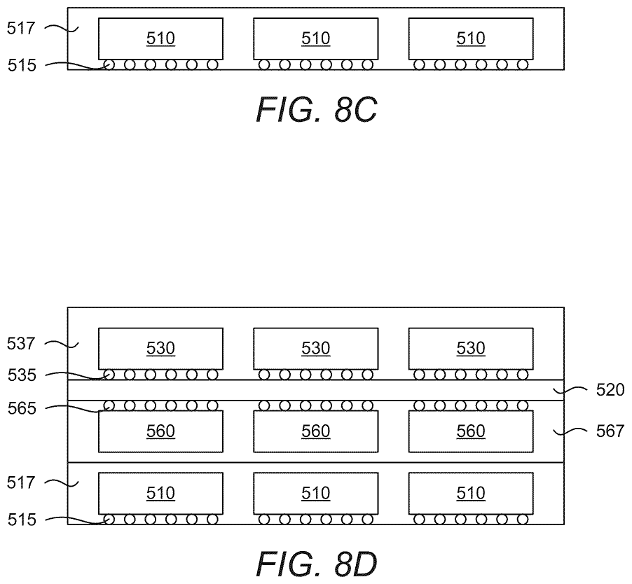

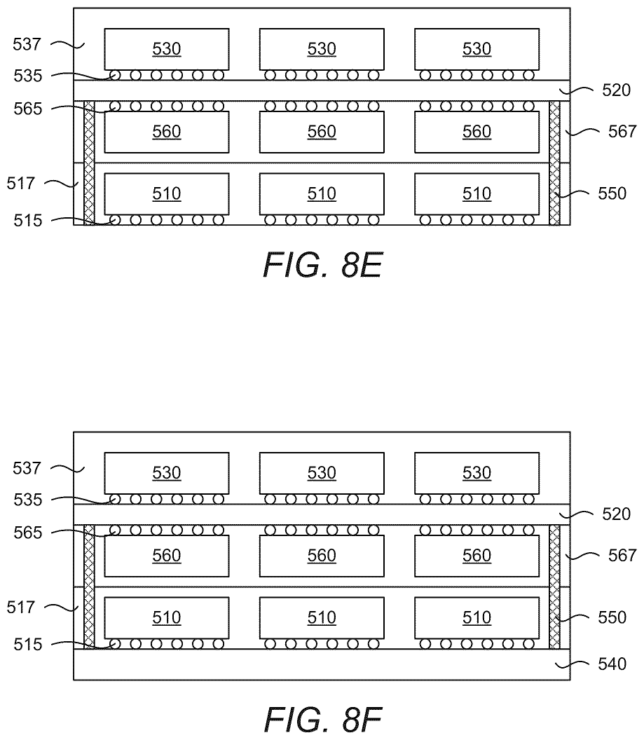

FIGS. 6A-8F illustrate examples of stages of fabricating a package, such as the package 500. There are at least two ways to fabricate the package. The first is the “chip first” way, and the second is the “chip last” way. FIGS. 6A-6D are particular to the chip first way, and FIGS. 7A-7D are particular to the chip last way. FIGS. 8A-8F are stages that are common to both.

As mentioned, FIGS. 6A-6D illustrate stages particular to the chip first process. FIG. 6A illustrates a stage in which an adhesive tape 606 may be applied on a carrier 603.

FIG. 6B illustrates a stage in which the third chip 530 may be placed on the adhesive tape 606. The third bumps 535 may face the adhesive tape 606. The third chips 530 and the adhesive tape 606 may be overmolded with a molding material to form the third mold 537. The upper side of the third mold 537 may be planarized to a desired thickness. Note that in FIG. 6B, multiple third chips 530 are shown. This is to illustrate that a wafer level processing may be performed. Thereafter, the processed wafer may be singulated to individual packages.

FIG. 6C illustrates a stage in which the carrier 603 and the adhesive tape 606 may be removed.

FIG. 6D illustrates a stage in which the second substrate 520 may be provided on the third chip 530 (e.g., on the third bumps 535) and on the third mold 537.

As mentioned, FIGS. 7A-7D illustrate stages particular to the chip last process. FIG. 7A illustrates a stage in which an adhesive tape 706 may be applied on a carrier 703.

FIG. 7B illustrates a stage in which the second substrate 520 may be formed on the adhesive tape 706.

FIG. 7C illustrates a stage in which the third chip 530 may be placed on the second substrate 520. The third bumps 535 may face the second substrate 520. The third chips 530 and the second substrate 520 may be overmolded with a molding material to form the third mold 537. The upper side of the third mold 537 may be planarized to a desired thickness. Note that multiple third chips 530 are shown implying that a wafer level processing may be performed, and the processed wafer may be singulated to individual packages.

FIG. 7D illustrates a stage in which the carrier 703 and the adhesive tape 706 may be removed.

In both FIGS. 6D and 7D, overmolding may result in forming the third mold 537 to encapsulate, at least partially, the third chip 530 (the side surface and the non-active side surface), in which the third chip 530 is in electrical contact with the upper surface of the second substrate 520. Process then may proceed to FIGS. 8A-8F.

FIG. 8A illustrates a stage in which the second chip 560 may be bonded on the lower surface of the second substrate 520. The second bumps 565 of the second chip 560 may be in electrical contact with the lower surface of the second substrate 520.

FIG. 8B illustrates a stage in which the lower surface of the second substrate 520 and the second chip 560 may be overmolded to form the second mold 567 encapsulating, at least partially, the side surfaces and the non-active side surface of the second chip 560. Also, the surface of the second mold 567 opposite the second substrate 520 may be planarized to a desired thinness.

FIG. 8C illustrates a stage in which the first chip 510 may be overmolded to form the first mold 517 encapsulating, at least partially, the side surfaces and the non-active side surface of the second chip 560. Also, the surface of the first mold 517 opposite the first substrate 540 (placed later in the process) may be planarized to a desired thinness. The stage of FIG. 8C may be separate from the stage of 8B. That is, they need not follow one another. It may be sufficient that they be performed.

FIG. 8D illustrates a stage in which the first mold 517 may be placed on the second mold 567 such that the non-active side of the first chip 510 faces the non-active side of the second chip 560. Recall that before placing the first and second molds 517, 567 together, they may be thinned as desired.

FIG. 8E illustrates a stage in which TMVs 550 may be formed within the first and second molds 517, 567.

FIG. 8F illustrates a stage in which the first substrate 540 may be placed on the first chip 510. In an aspect, the first bumps 515 of the first chip 510 may be in electrical contact with the upper surface of first substrate 540 after the placement.

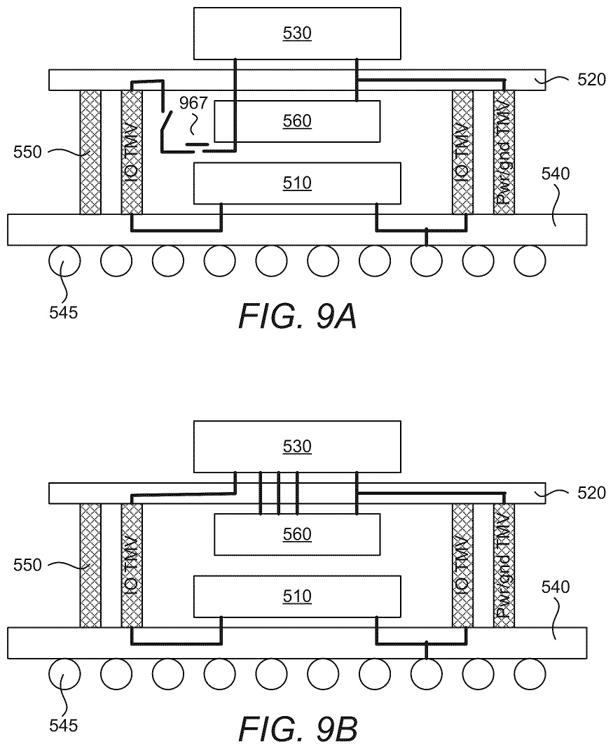

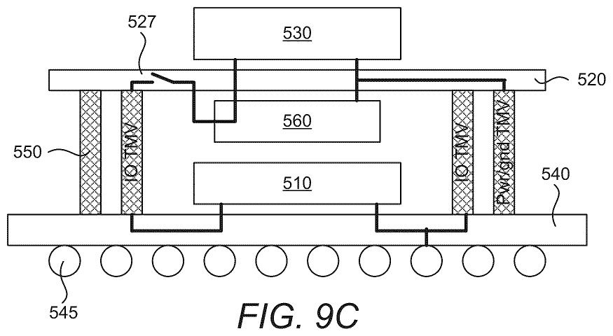

Recall from above that the package 500 having stacked substrates can allow logic flows to be achieved. FIGS. 9A, 9B and 9C illustrate simplified view of the package (e.g., without first, second and third molds) so that the implemented logic can be more easily viewed. FIG. 9A illustrates a multiplexed IO inside power distribution network (PDN) in which the DRAM 530 is conventionally used. In FIG. 9B, DRAM with lite IOs (vertical connections of the second substrate 520) is illustrated. This design can significantly increase the bandwidth. In FIG. 9C, interposer (e.g., second substrate 520) may include IGZO/TFT switches.

In these designs, IO switches can cut-off redundant switching from DRAM to the logic die when PNM block inside the PNM die is computing or accessing the DRAM. Also, MBIST can be used for the DRAM manufacturing tests. Power and Ground TMVs may be used to distribute power and ground (i.e. Vdd/Vss) to both PNM and DRAM. Interposers may be used to route internal and external signals across DRAM, PNM, and external package balls. DRAM IO may drive large loads (and may be JEDEC compatible) while lite-IO may be custom-made to drive PNM-only through vertical short connections within the second substrate.

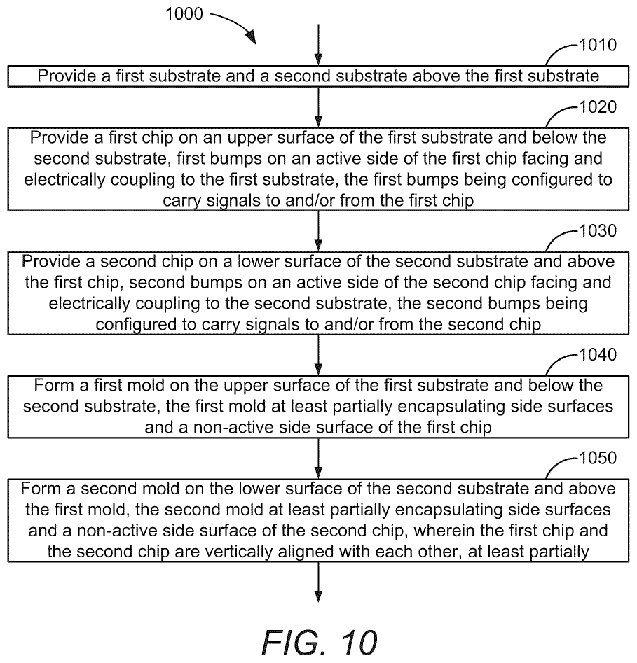

FIG. 10 illustrates a flow chart of an example method 1000 of fabricating a package, such as the package 500 in accordance with one or more aspects of the disclosure.

In block 1010, a first substrate 540 may be provided and a second substrate 520 may be provided above the first substrate 540.

In block 1020, a first chip 510 may be provided on an upper surface of the first substrate 540 and below the second substrate 520. First bumps 515 on an active side of the first chip 510 may face and electrically couple to the first substrate 540. The first bumps 515 may be configured to carry signals to and/or from the first chip 510.

In block 1030, a second chip 560 may be provided on a lower surface of the second substrate 520 and above the first chip 510. Second bumps 565 on an active side of the second chip 560 may face and electrically couple to the second substrate 520. The second bumps 565 may be configured to carry signals to and/or from the second chip 560.

In block 1040, a first mold 517 may be formed on the upper surface of the first substrate 540 and below the second substrate 520. The first mold 517 may encapsulate, at least partially, side surfaces and a non-active side surface of the first chip 510.

In block 1050, a second mold 567 may be formed on the lower surface of the second substrate 520 and above the first mold 517. The second mold 567 may encapsulate, at least partially, side surfaces and a non-active side surface of the second chip 560. The first chip 510 and the second chip 560 may be vertically aligned with each other, at least partially.

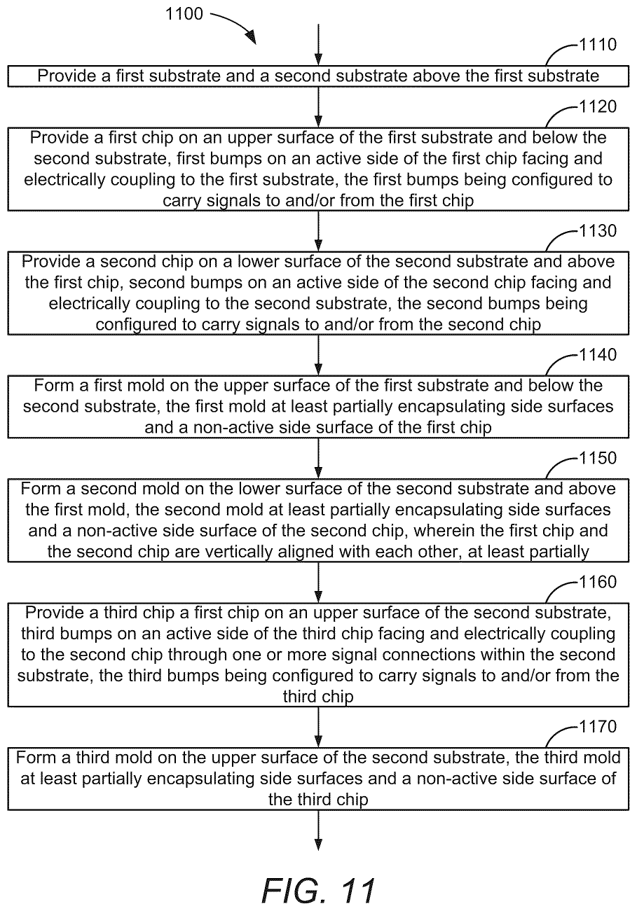

FIG. 11 illustrates a flow chart of another example method 1100 of fabricating a package, such as the package 500 in accordance with one or more aspects of the disclosure. The method 1100 may be viewed as a more detailed version of the method 1000.

Block 1110 may be similar to block 1010. That is, in block 1110, a first substrate 540 may be provided and a second substrate 520 may be provided above the first substrate 540.

Block 1120 may be similar to block 1020. That is, in block 1120, a first chip 510 may be provided on an upper surface of the first substrate 540 and below the second substrate 520. First bumps 515 on an active side of the first chip 510 may face and electrically the first substrate 540. The first bumps 515 may be configured to carry signals to and/or from the first chip 510.

Block 1130 may be similar to block 1030. That is, in block 1130, a second chip 560 may be provided on a lower surface of the second substrate 520 and above the first chip 510. Second bumps 565 on an active side of the second chip 560 may face and electrically the second substrate 520. The second bumps 565 may be configured to carry signals to and/or from the second chip 560.

Block 1140 may be similar to block 1040. That is, in block 1140, a first mold 517 may be formed on the upper surface of the first substrate 540 and below the second substrate 520. The first mold 517 may encapsulate, at least partially, side surfaces and a non-active side surface of the first chip 510.

Block 1150 may be similar to block 1050. That is, in block 1150, a second mold 567 may be formed on the lower surface of the second substrate 520 and above the first mold 517. The second mold 567 may encapsulate, at least partially, side surfaces and a non-active side surface of the second chip 560. The first chip 510 and the second chip 560 may be vertically aligned with each other, at least partially.

In block 1160, a third chip 530 may be provided on an upper surface of the second substrate 520. Third bumps 535 on an active side of the third chip 530 may face and electrically the second chip 560 through one or more signal connections within the second substrate 520. The third bumps 535 may be configured to carry signals to and/or from the third chip 530.

In block 1170, a third mold 537 may be formed on the upper surface of the second substrate 520. The third mold 537 may encapsulate, at least partially, side surfaces and a non-active side surface of the third chip 530.

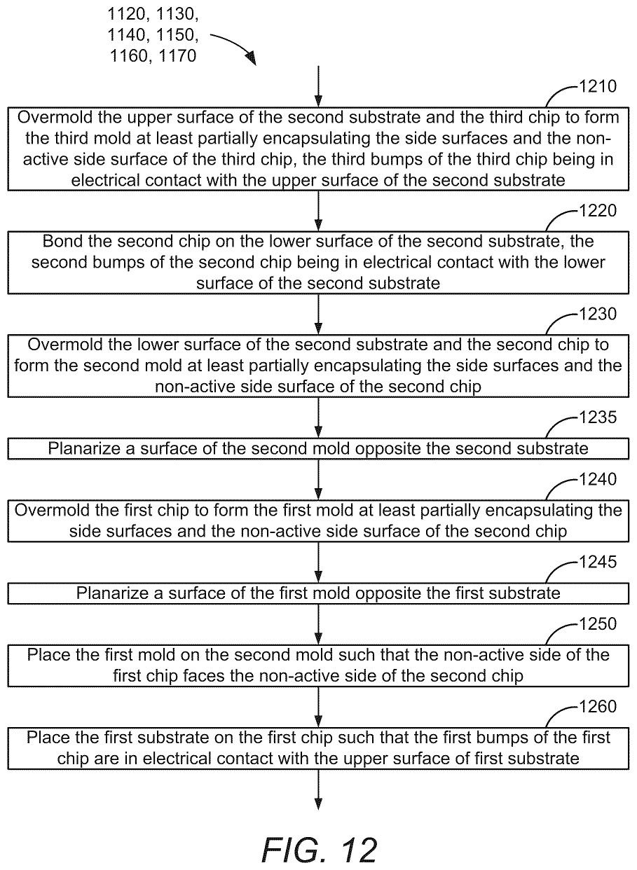

FIG. 12 illustrates a flow chart of an example process to implement blocks 1120, 1130, 1140, 1150 and 1160. In block 1210, the upper surface of the second substrate 520 and the third chip 530 may be overmolded to form the third mold 517. The third mold 517 may encapsulate, at least partially, the side surfaces and the non-active side surface of the third chip 530. The third bumps 535 of the third chip 530 may be in electrical contact with the upper surface of the second substrate 520.

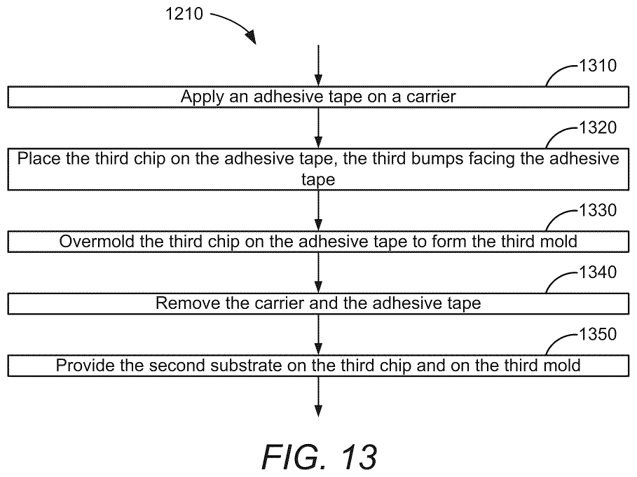

FIG. 13 illustrates a flow chart of an example process to implement block 1210. In this particular instance, a flow chart of the “chip first” process is shown. Refer to fabrication stages illustrated in FIGS. 6A-6D. In block 1310, an adhesive tape 606 may be applied on a carrier 603.

In block 1320, the third chips 530 may be placed on the adhesive tape 606. The third bumps 535 may face the adhesive tape 606.

In block 1330, the third chips 530 on the adhesive tape 606 may be overmolded with a molding material to form the third mold 537.

In block 1340, the carrier 603 and the adhesive tape 606 may be removed.

In block 1350, the second substrate 520 may be provided on the third chip 530 (e.g., on the third bumps 535) and on the third mold 537.

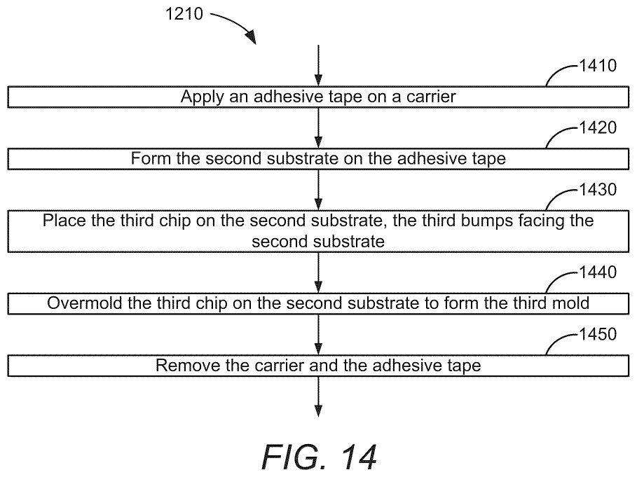

FIG. 14 illustrates a flow chart of another example process to implement block 1210. In this particular instance, a flow chart of the “chip last” process is shown. Refer to fabrication stages illustrated in FIGS. 7A-7D. In block 1410, an adhesive tape 706 may be applied on a carrier 703.

In block 1420, the second substrate 520 may be formed on the adhesive tape 706.

In block 1430, the third chips 530 may be placed on the second substrate 520. The third bumps 535 may face the second substrate 520.

In block 1440, the third chips 530 on the second substrate 520 may be overmolded with a molding material to form the third mold 537.

In block 1450, the carrier 703 and the adhesive tape 706 may be removed.

Referring back to FIG. 12, in block 1220, the second chip 560 may be bonded on the lower surface of the second substrate 520. The second bumps 565 of the second chip 560 may be in electrical contact with the lower surface of the second substrate 520.

In block 1230, the lower surface of the second substrate 520 and the second chip 560 may be overmolded to form the second mold 567. The second mold 567 may encapsulate, at least partially, the side surfaces and the non-active side surface of the second chip 560.

In block 1235, a surface of the second mold 567 opposite the second substrate 520 may be planarized to a desired thinness.

In block 1240, the first chip 510 may be overmolded to form the first mold 517. The first mold 517 may encapsulate, at least partially, the side surfaces and the non-active side surface of the second chip 560.

In block 1245, a surface of the first mold 517 opposite the first substrate 540 may be planarized to a desired thinness.

In block 1250, the first mold 517 may be placed on the second mold 567 such that the non-active side of the first chip 510 faces the non-active side of the second chip 560.

In block 1260, the first substrate 540 may be placed on the first chip 510 such that the first bumps 515 of the first chip 510 are in electrical contact with the upper surface of first substrate 540.

The following should be noted regarding the flow indicated in FIGS. 10-14. Unless otherwise indicated, the flow of blocks does not necessarily limit the ordering in which the blocks may be performed. In other words, the blocks may be performed in any order that is logical.

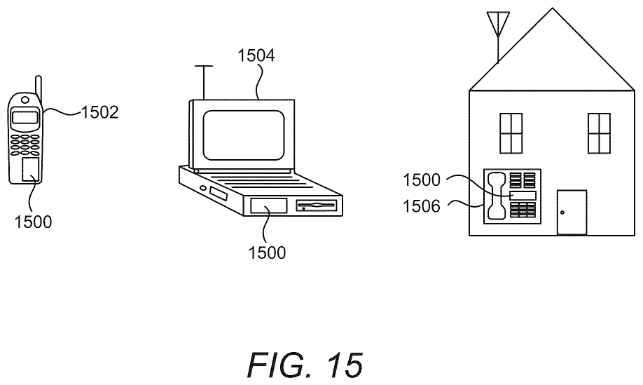

FIG. 15 illustrates various electronic devices 1500 that may be integrated with any of the aforementioned packages (e.g., package 500) in accordance with various aspects of the disclosure. For example, a mobile phone device 1502, a laptop computer device 1504, and a fixed location terminal device 1506 may each be considered generally user equipment (UE) and may include one or more packages (e.g., package 500) as described herein. The devices 1502, 1504, 1506 illustrated in FIG. 15 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A package, comprising: a first substrate and a second substrate above the first substrate; a first chip on an upper surface of the first substrate and below the second substrate, first bumps on an active side of the first chip facing and electrically coupled to the first substrate, the first bumps configured to carry signals to and/or from the first chip; a second chip on a lower surface of the second substrate and above the first chip, second bumps on an active side of the second chip facing and electrically coupled to the second substrate, the second bumps configured to carry signals to and/or from the second chip; a first mold on the upper surface of the first substrate and below the second substrate, the first mold at least partially encapsulating side surfaces and a non-active side surface of the first chip; and a second mold on the lower surface of the second substrate and above the first mold, the second mold at least partially encapsulating side surfaces and a non-active side surface of the second chip, wherein the first chip and the second chip are vertically aligned with each other, at least partially.

Clause 2: The package of clause 1, further comprising: a third chip on an upper surface of the second substrate, third bumps on an active side of the third chip facing and electrically coupled to the second chip through one or more signal connections within the second substrate, the third bumps configured to carry signals to and/or from the third chip, and a third mold on the upper surface of the second substrate, the third mold at least partially encapsulating side surfaces and a non-active side surface of the third chip.

Clause 3: The package of clause 2, wherein the first chip is a logic chip, the second chip is a processing near memory (PNM) chip, the third chip is a memory chip, or any combination thereof.

Clause 4: The package of clause 3, wherein the memory chip is a dynamic random-access memory (DRAM) chip.

Clause 5: The package of any of clauses 2-4, wherein pitches between adjacent second bumps and between adjacent third bumps are less than 1 μm, wherein one or more second bumps and vertically connected to one or more third bumps through corresponding one or more vertical signal connections within the second substrate, and wherein the second chip is configured to access the third chip through the one or more vertical signal connections.

Clause 6: The package of clause 5, wherein the second chip is a processing near memory (PNM) chip and the third chip is a memory chip, and wherein the PNM chip is configured to perform memory built-in self-test (MBIST) of the memory chip through the one or more vertical signal connections within the second substrate.

Clause 7: The package of clause 6, wherein the first chip is a logic chip, wherein the package further comprises one or more thin film transistors (TFT) within the second substrate, at least one TFT configured to switch on/off an electrical connection between the first and second substrates, and wherein the PNM chip is configured to control the one or more TFTs to cutoff redundant switching from the memory chip to the logic chip when the PNM chip is accessing the memory chip.

Clause 8: The package of any of clauses 5-7, wherein a thickness of the second substrate is 70 μm or less.

Clause 9: The package of any of clauses 1-8, further comprising: one or more through-mold vias (TMV) between the first and second substrates within the first and second molds, the one or more TMVs electrically coupling the first and second substrates with each other.

Clause 10: The package of clause 9, further comprising: one or more thin film transistors (TFT) within the second substrate, at least one TFT configured to switch on/off an electrical connection between the first and second substrates through at least one TMV.

Clause 11: The package of any of clauses 10, wherein an operation of the at least one TFT is under control of the second chip.

Clause 12: The package of any of clauses 1-11, wherein the second substrate is a coreless substrate.

Clause 13: The package of any of clauses 1-12, wherein the first and second molds are separate molds that are in contact with each other.

Clause 14: The package of any of clauses 1-13, wherein a thermal conductivity of the first mold is equal to or greater than 1 W/m−K, a thermal conductivity of the second mold is equal to or greater than 1 W/m−K, or both.

Clause 15: The package of any of clauses 1-14, wherein the package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 16: A method of fabricating a package, the method comprising: providing a first substrate and a second substrate above the first substrate; providing a first chip on an upper surface of the first substrate and below the second substrate, first bumps on an active side of the first chip facing and electrically coupled to the first substrate, the first bumps configured to carry signals to and/or from the first chip; providing a second chip on a lower surface of the second substrate and above the first chip, second bumps on an active side of the second chip facing and electrically coupled to the second substrate, the second bumps configured to carry signals to and/or from the second chip; forming a first mold on the upper surface of the first substrate and below the second substrate, the first mold at least partially encapsulating side surfaces and a non-active side surface of the first chip; and forming a second mold on the lower surface of the second substrate and above the first mold, the second mold at least partially encapsulating side surfaces and a non-active side surface of the second chip, wherein the first chip and the second chip are vertically aligned with each other, at least partially.

Clause 17: The method of clause 16, further comprising: providing a third chip on an upper surface of the second substrate, third bumps on an active side of the third chip facing and electrically coupled to the second chip through one or more signal connections within the second substrate, the third bumps configured to carry signals to and/or from the third chip, and forming a third mold on the upper surface of the second substrate, the third mold at least partially encapsulating side surfaces and a non-active side surface of the third chip.

Clause 18: The method clause 17, wherein the first chip is a logic chip, the second chip is a processing near memory (PNM) chip, the third chip is a memory chip, or any combination thereof.

Clause 19: The method clause 18, wherein the memory chip is a dynamic random-access memory (DRAM) chip.

Clause 20: The method of any of clauses 17-19, wherein providing the first chip, providing the second chip, forming the first mold, forming the second mold, providing the third chip, and forming the third mold comprises: overmolding the upper surface of the second substrate and the third chip to form the third mold at least partially encapsulating the side surfaces and the non-active side surface of the third chip, the third bumps of the third chip in electrical contact with the upper surface of the second substrate; bonding the second chip on the lower surface of the second substrate, the second bumps of the second chip in electrical contact with the lower surface of the second substrate; overmolding the lower surface of the second substrate and the second chip to form the second mold at least partially encapsulating the side surfaces and the non-active side surface of the second chip; overmolding the first chip to form the first mold at least partially encapsulating the side surfaces and the non-active side surface of the second chip; placing the first mold on the second mold such that the non-active side of the first chip faces the non-active side of the second chip; and placing the first substrate on the first chip such that the first bumps of the first chip are in electrical contact with the upper surface of first substrate.

Clause 21: The method of clause 20, wherein overmolding the upper surface of the second substrate and the third chip to form the third mold comprises: applying an adhesive tape on a carrier; placing the third chip on the adhesive tape, the third bumps facing the adhesive tape; overmolding the third chip on the adhesive tape to form the third mold; removing the carrier and the adhesive tape; and providing the second substrate on the third chip and on the third mold.

Clause 22: The method of clause 20, wherein overmolding the upper surface of the second substrate and the third chip to form the third mold comprises: applying an adhesive tape on a carrier; forming the second substrate on the adhesive tape; placing the third chip on the second substrate, the third bumps facing the second substrate; overmolding the third chip on the second substrate to form the third mold; and removing the carrier and the adhesive tape.

Clause 23: The method of any of clauses 20-22, wherein providing the first chip, providing the second chip, forming the first mold, forming the second mold, providing (Y50) the third chip, and forming the third mold further comprises: subsequent to overmolding to form the second mold and prior to placing the first mold on the second mold, planarizing a surface of the second mold opposite the second substrate; or planarizing a surface of the first mold opposite the first substrate; or both.

Clause 24: The method of any of clauses 17-23, wherein pitches between adjacent second bumps and between adjacent third bumps are less than 1 μm, wherein one or more second bumps and vertically connected to one or more third bumps through corresponding one or more vertical signal connections within the second substrate, and wherein the second chip is configured to access the third chip through the one or more vertical signal connections.

Clause 25: The method of clause 24, wherein the second chip is a processing near memory (PNM) chip and the third chip is a memory chip, and wherein the PNM chip is configured to perform memory built-in self-test (MBIST) of the memory chip through the one or more vertical signal connections within the second substrate.

Clause 26: The method of any of clauses 16-25, further comprising: forming one or more through-mold vias (TMV) between the first and second substrates within the first and second molds, the one or more TMVs electrically coupling the first and second substrates with each other.

Clause 27: The method of clause 26, wherein one or more thin film transistors (TFT) are formed within the second substrate, at least one TFT configured to switch on/off an electrical connection between the first and second substrates through at least one TMV.

Clause 28: The method of any of clauses 16-27, wherein the second substrate is a coreless substrate.

Clause 29: The method of any of clauses 16-28, wherein the first and second molds are separate molds that are in contact with each other.

Clause 30: The method of any of clauses 16-29, wherein a thermal conductivity of the first mold is equal to or greater than 1 W/m−K, a thermal conductivity of the second mold is equal to or greater than 1 W/m−K, or both.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth® (BT), Bluetooth® Low Energy (BLE), IEEE 802.11 (Wi-Fi®), and IEEE 802.15.4 (Zigbee/Thread) or other protocols that may be used in a wireless communications network or a data communications network. Bluetooth® Low Energy (also known as Bluetooth® LE, BLE, and Bluetooth® Smart) is a wireless personal area network technology designed and marketed by the Bluetooth® Special Interest Group intended to provide considerably reduced power consumption and cost while maintaining a similar communication range. BLE was merged into the main Bluetooth® standard in 2010 with the adoption of the Bluetooth® Core Specification Version 4.0 and updated in Bluetooth® 5.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A package, comprising:
a first substrate and a second substrate above the first substrate;
a first chip on an upper surface of the first substrate and below the second substrate, first bumps on an active side of the first chip facing and electrically coupled to the first substrate, the first bumps configured to carry signals to and/or from the first chip;
a second chip on a lower surface of the second substrate and above the first chip, second bumps on an active side of the second chip facing and electrically coupled to the second substrate, the second bumps configured to carry signals to and/or from the second chip;
a first mold on the upper surface of the first substrate and below the second substrate, the first mold at least partially encapsulating side surfaces and a non-active side surface of the first chip; and
a second mold on the lower surface of the second substrate and above the first mold, the second mold at least partially encapsulating side surfaces and a non-active side surface of the second chip,
wherein the first chip and the second chip are vertically aligned with each other, at least partially.

2. The package of claim 1, further comprising:
a third chip on an upper surface of the second substrate, third bumps on an active side of the third chip facing and electrically coupled to the second chip through one or more signal connections within the second substrate, the third bumps configured to carry signals to and/or from the third chip, and
a third mold on the upper surface of the second substrate, the third mold at least partially encapsulating side surfaces and a non-active side surface of the third chip.

3. The package of claim 2, wherein
the first chip is a logic chip,
the second chip is a processing near memory (PNM) chip,
the third chip is a memory chip, or
any combination thereof.

4. The package of claim 3, wherein the memory chip is a dynamic random-access memory (DRAM) chip.

5. The package of claim 2,
wherein pitches between adjacent second bumps and between adjacent third bumps are less than 1 μm,
wherein one or more second bumps and vertically connected to one or more third bumps through corresponding one or more vertical signal connections within the second substrate, and
wherein the second chip is configured to access the third chip through the one or more vertical signal connections.

6. The package of claim 5,
wherein the second chip is a processing near memory (PNM) chip and the third chip is a memory chip, and
wherein the PNM chip is configured to perform memory built-in self-test (MBIST) of the memory chip through the one or more vertical signal connections within the second substrate.

7. The package of claim 6,
wherein the first chip is a logic chip,
wherein the package further comprises one or more thin film transistors (TFTs) within the second substrate, at least one TFT of the one or more TFTs is configured to switch on/off an electrical connection between the first and second substrates, and
wherein the PNM chip is configured to control the one or more TFTs to cutoff redundant switching from the memory chip to the logic chip when the PNM chip is accessing the memory chip.

8. The package of claim 5, wherein a thickness of the second substrate is 70 μm or less.

9. The package of claim 1, further comprising:
one or more through-mold vias (TMVs) between the first and second substrates within the first and second molds, the one or more TMVs electrically coupling the first and second substrates with each other.

10. The package of claim 9, further comprising:
one or more thin film transistors (TFTs) within the second substrate, wherein at least one TFT of the one or more TFTs is configured to switch on/off an electrical connection between the first and second substrates through at least one TMV.

11. The package of claim 10, wherein an operation of the at least one TFT is under control of the second chip.

12. The package of claim 1, wherein the second substrate is a coreless substrate.

13. The package of claim 1, wherein the first and second molds are separate molds that are in contact with each other.

14. The package of claim 1, wherein
a thermal conductivity of the first mold is equal to or greater than 1 W/m−K,
a thermal conductivity of the second mold is equal to or greater than 1 W/m−K, or
both.

15. The package of claim 1, wherein the package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

16. A method of fabricating a package, the method comprising:
providing a first substrate and a second substrate above the first substrate;
providing a first chip on an upper surface of the first substrate and below the second substrate, first bumps on an active side of the first chip facing and electrically coupled to the first substrate, the first bumps configured to carry signals to and/or from the first chip;
providing a second chip on a lower surface of the second substrate and above the first chip, second bumps on an active side of the second chip facing and electrically coupled to the second substrate, the second bumps configured to carry signals to and/or from the second chip;
forming a first mold on the upper surface of the first substrate and below the second substrate, the first mold at least partially encapsulating side surfaces and a non-active side surface of the first chip; and
forming a second mold on the lower surface of the second substrate and above the first mold, the second mold at least partially encapsulating side surfaces and a non-active side surface of the second chip,
wherein the first chip and the second chip are vertically aligned with each other, at least partially.

17. The method of claim 16, further comprising:
providing a third chip on an upper surface of the second substrate, third bumps on an active side of the third chip facing and electrically coupled to the second chip through one or more signal connections within the second substrate, the third bumps configured to carry signals to and/or from the third chip, and
forming a third mold on the upper surface of the second substrate, the third mold at least partially encapsulating side surfaces and a non-active side surface of the third chip.

18. The method of claim 17, wherein
the first chip is a logic chip,
the second chip is a processing near memory (PNM) chip,
the third chip is a memory chip, or
any combination thereof.

19. The method of claim 18, wherein the memory chip is a dynamic random-access memory (DRAM) chip.

20. The method of claim 17, wherein providing the first chip, providing the second chip, forming the first mold, forming the second mold, providing the third chip, and forming the third mold comprises:
overmolding the upper surface of the second substrate and the third chip to form the third mold at least partially encapsulating the side surfaces and the non-active side surface of the third chip, the third bumps of the third chip in electrical contact with the upper surface of the second substrate;
bonding the second chip on the lower surface of the second substrate, the second bumps of the second chip in electrical contact with the lower surface of the second substrate;
overmolding the lower surface of the second substrate and the second chip to form the second mold at least partially encapsulating the side surfaces and the non-active side surface of the second chip;
overmolding the first chip to form the first mold at least partially encapsulating the side surfaces and the non-active side surface of the second chip;
placing the first mold on the second mold such that the non-active side of the first chip faces the non-active side of the second chip; and
placing the first substrate on the first chip such that the first bumps of the first chip are in electrical contact with the upper surface of first substrate.

21. The method of claim 20, wherein overmolding the upper surface of the second substrate and the third chip to form the third mold comprises:
applying an adhesive tape on a carrier;
placing the third chip on the adhesive tape, the third bumps facing the adhesive tape;
overmolding the third chip on the adhesive tape to form the third mold;
removing the carrier and the adhesive tape; and
providing the second substrate on the third chip and on the third mold.

22. The method of claim 20, wherein overmolding the upper surface of the second substrate and the third chip to form the third mold comprises:
applying an adhesive tape on a carrier;
forming the second substrate on the adhesive tape;
placing the third chip on the second substrate, the third bumps facing the second substrate;
overmolding the third chip on the second substrate to form the third mold; and
removing the carrier and the adhesive tape.

23. The method of claim 20, wherein providing the first chip, providing the second chip, forming the first mold, forming the second mold, providing the third chip, and forming the third mold further comprises:
subsequent to overmolding to form the second mold and prior to placing the first mold on the second mold,
planarizing a surface of the second mold opposite the second substrate; or
planarizing a surface of the first mold opposite the first substrate; or
both.

24. The method of claim 17,
wherein pitches between adjacent second bumps and between adjacent third bumps are less than 1 μm,
wherein one or more second bumps and vertically connected to one or more third bumps through corresponding one or more vertical signal connections within the second substrate, and
wherein the second chip is configured to access the third chip through the one or more vertical signal connections.

25. The method of claim 24,
wherein the second chip is a processing near memory (PNM) chip and the third chip is a memory chip, and
wherein the PNM chip is configured to perform memory built-in self-test (MBIST) of the memory chip through the one or more vertical signal connections within the second substrate.

26. The method of claim 16, further comprising:
forming one or more through-mold vias (TMVs) between the first and second substrates within the first and second molds, the one or more TMVs electrically coupling the first and second substrates with each other.

27. The method of claim 26, wherein one or more thin film transistors (TFTs) are formed within the second substrate, and at least one TFT of the one or more TFTs is configured to switch on/off an electrical connection between the first and second substrates through at least one TMV.

28. The method of claim 16, wherein the second substrate is a coreless substrate.

29. The method of claim 16, wherein the first and second molds are separate molds that are in contact with each other.

30. The method of claim 16, wherein
a thermal conductivity of the first mold is equal to or greater than 1 W/m−K,
a thermal conductivity of the second mold is equal to or greater than 1 W/m−K, or
both.
